(19) United States
(12) Patent Application Publication
(10) Pub. No.: US 2005/0082576 A1
(43) Pub. Date: Apr. 21, 2005

(54) Method and structure for compact transistor array layout

(76) Inventors: Ching-Kuo Wu, Taipei (TW); Shyh-Chyi Wong, Taipei (TW)

Correspondence Address: BIRCH STEWART KOLASCH & BIRCH, PO BOX 747, FALLS CHURCH, VA, 22040-0747, US

(21) Appl. No.: 10/833,036

(22) Filed: Apr. 28, 2004

(30) Foreign Application Priority Data
Oct. 17, 2003 (TW) 92128823

(51) Int. Cl. H01L 27/10

(52) U.S. Cl. 257/203

(57) ABSTRACT

A method and structure for a compact transistor array layout is applied in a bipolar transistor integration process for equalizing distributed reactance in a wafer. The structure has a plurality of unitization elements with a first element and a second element for receiving an input signal. The first element and the second element are composed of a plurality of transistors. A plurality of wires used to feed the input signal in the unitization elements are arranged in multi-level branches manner. The wires can have predetermined resistance, capacitance, or inductance and the input signal is equidistant from the unitization elements. A multi-dimensional layout space is formed by arranging the unitization elements in order. The inventive structure can be applied in heterojunction bipolar transistor (HBT) or bipolar junction transistor (BJT) so that more transistors can be installed in a unit volume.

### BACKGROUND OF THE INVENTION

1. Field of the Invention

The present invention relates to a method and structure for a compact transistor array layout, and particularly, to a method and structure for symmetrically feeding (tree-like feeding) the input signal to the elements (transistors) in multi-level branches manner so that more transistors can be arranged in a unit volume.

2. Description of the Prior Art

Nowadays, new communication products are continuously developed, and microwave technology has gradually matured. For example, the power amplifier (PA) in the communication system requires power of several watts for operation, and therefore, the manufacturers constantly struggle for searching out the method to install more transistors in a unit volume. However, due to the manufacturing process limitation, on one wafer the oriented directions of the transistors have to be the same. This limits the number of die singularization amounts for the wafer.

Reference is made to FIG. 1A and 1B. FIG. 1A and 1B are perspective diagrams of layouts of transistors in the prior art. In FIG. 1A, the transistors are arranged along a direction parallel to an arrangement direction of figures in the transistor, namely, the emitter (E), the base (B), and the collector (C). In the prior art, an input signal is fed via an input end 10, and the input signal is then fed into the first transistor 20 and the second transistor 30 separately. However, the distance between the input end 10 and an x point (where the first transistor 20 is placed) is different from that between the input end 10 and an x′ point (where the first transistor 30 is placed). The second transistor 30 closer to the input end 10 has a relatively earlier conduction time, and tends to have continuously increased current due to the positive temperature feedback effect. Therefore, in the situation of long time usage, the second transistor 30 closer to the input end 10 tends to be burned out. In addition, due to the distance difference, the quality of the circuit is degraded by non-uniform distributed reactance.

In FIG. 1B, the transistors are arranged in a direction vertical to the arrangement direction of figures in the transistor. In this prior art, an input signal is fed via the input end 10, and the input signal is then fed into the first transistor 20 and the second transistor 30 separately. Similarly, the distance between the input end 10 and a y point (where the first transistor 20 is placed) is different from that between the input end 10 and a y′ point (where the first transistor 30 is placed). Therefore, the conduction time of the first transistor 20 is inconsistent with that of the second transistor 30. The problems of positive temperature feedback and non-uniform distributed reactance will still occur. According to FIGS. 1A and 1B, the transistor array has a large aspect ratio when large amount of transistor are arranged in either horizontal or vertical fashion. This limits the number of die singularization amounts for the wafer.

FIG. 2 is a perspective diagram of a field effect transistor (FET) described in U.S. Pat. No. 6,081,006. In the field effect transistor structure 40, the distance between the input end 50 and point z is different from that between the input end 50 and point z′, and therefore, in practical manufacturing, non-uniform distributed reactance is generated. Furthermore, the arrangement of the transistor structure 40 is extremely long to preclude the possibility for installing more field effect transistors in a unit volume and limit the number of the singularization of the wafer.

### SUMMARY OF THE INVENTION

Therefore, the main object of the present invention is to provide a method and structure for a compact transistor array layout. A plurality of wires with multi-level branches architecture are applied to feed symmetrically (tree feeding) the input signal to the elements (transistors) so that more transistors can be installed in a unit volume. Therefore, the layout is reduced. Furthermore, the distributed reactance between the wires is equalized and the induction between the circuits is reduced so as to promote efficiency and power performance.

In order to achieve the above mentioned object, the structure for a compact transistor array layout according to the present invention comprises a plurality of unitization elements composed of a first element and a second element for receiving an input signal. The first element and the second element are composed of a plurality of transistors, a plurality of wires used for feeding the input signal in the unitization elements and arranged in multi-level branches manner, in which the wires are so provided with predetermined resistance, capacitance, or inductance that the feeding position of the input signal is equidistant from the unitization elements. The structure for a compact transistor array layout according to the present invention can also be implemented by a multi-dimensional layout space formed by arranging the unitization elements in order. Therefore, more transistors can be installed in a unit volume, and the layout is reduced. Furthermore, the distributed reactance in the wafer is effectively reduced so as to promote the yield and decrease the unit cost.

### BRIEF DESCRIPTION OF THE DRAWINGS

The accompanying drawings, which are incorporated in and form part of the specification in which like numerals designate like parts, illustrate preferred embodiments of the present invention and together with the description, serve to explain the principles of the invention. In the drawings:

FIG. 1A shows that the transistors are arranged to be parallel to the element layout in the prior art;

FIG. 1B shows that the transistors are arranged to be vertical to the element layout in the prior art;

FIG. 2 shows the arrangement of the field effect transistor (FET) described in U.S. Pat. No. 6,081,006;

FIG. 3 is a perspective diagram of a unitization element for a compact transistor array layout method and structure according to the present invention;

FIG. 4 is a perspective diagram of an embodiment according to the present invention;

FIG. 5 is a perspective diagram of another feeding unit wire structure according to the present invention;

FIG. 6 is a perspective diagram of a structure with multi-level branches according to the present invention;

FIG. 7 is a perspective diagram of a two-dimensional planar array layout according to the present invention; and

FIG. 8 is a flowchart of a method according to the present invention.

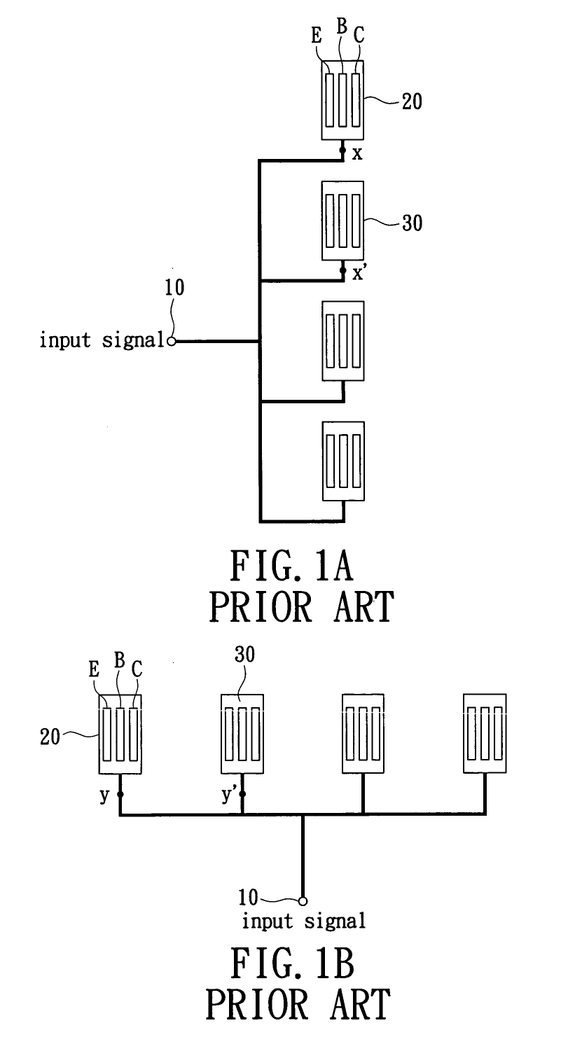

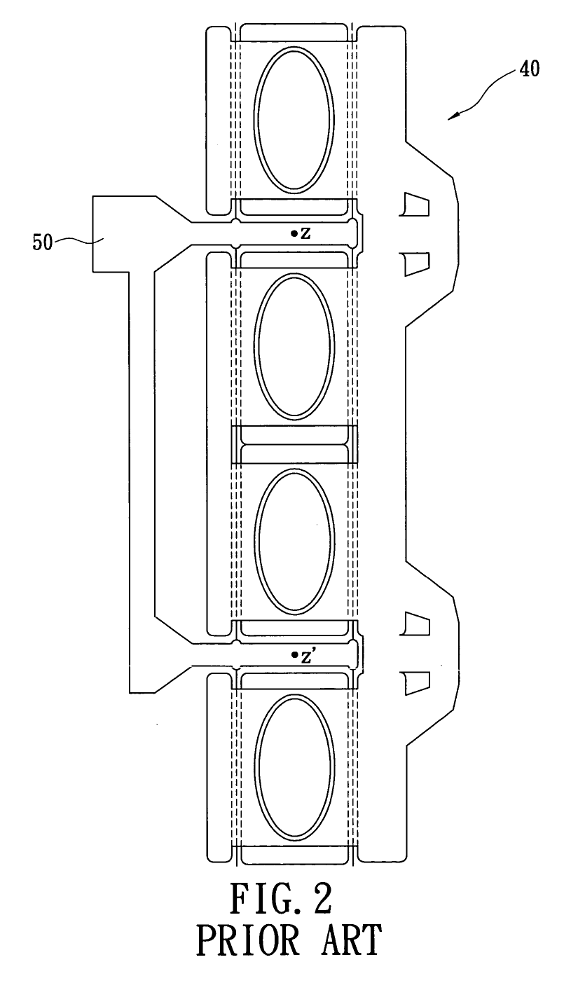

### DETAILED DESCRIPTION OF THE PREFERRED EMBODIMENT

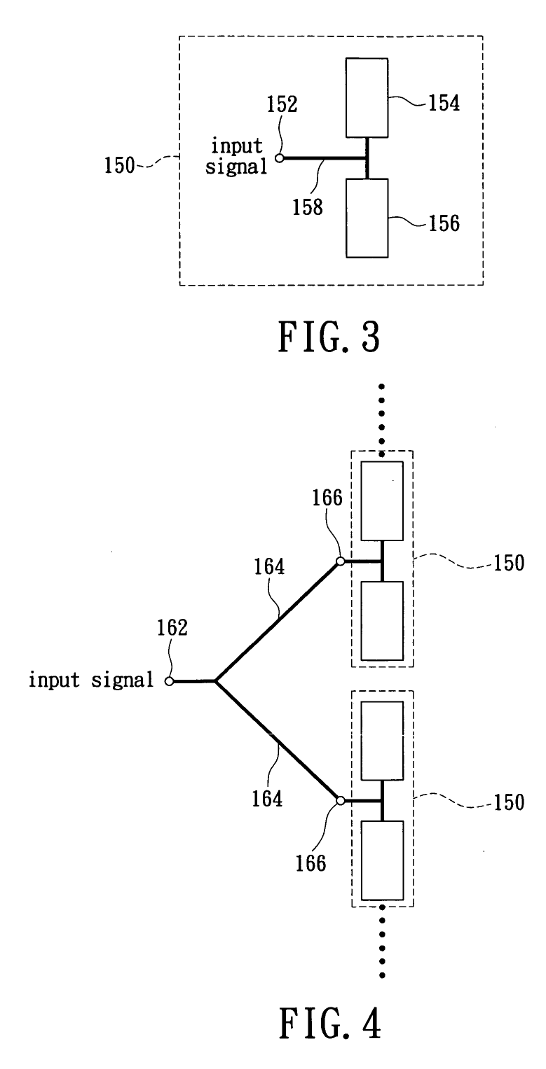

The present invention relates to a method and structure for a compact transistor array layout. The present invention is applied in the integration process of the bipolar transistor, such as heterojunction bipolar transistor (HBT) or the bipolar junction transistor (BJT). Therefore, more transistors can be installed in a unit volume so as to achieve a compact layout. Furthermore, the distributed reactance in the wafer is effectively reduced to promote the yield and decrease the unit cost. The distributed reactance between the wires is equalized, and the induction between the wires is reduced. FIG. 3 is a perspective diagram of a unitization element 150 for a compact transistor array layout according to the present invention. By connecting a plurality of unitization elements 150, a transistor array layout is formed. By using this unitization element 150, the peripherals are easily grounded, and the feedback oscillation between the transistors can be reduced. An input signal is inject input via an input end 152, and then the input signal is symmetrically fed into a first element 154 and a second element 156 by the wire 158. The first element 154 and second element 156 can be silicon-based structures with predetermined Si ratio, such as the heterojunction bipolar transistor (HBT) or the bipolar transistor (BJT).

When the input signal is symmetrically fed to location equidistant to the first element 154 and the second element 156 from the input end 152, the path lengths from the input signal to the first element 154 and the second element 156 are uniform. By combining different metal layers, poly silicon, metal silicide or diffusion layers, the wire 158 can be formed in the semiconductor process. The wire 158 not only can be used for connecting the first element 154 and the second element 156, but also can provide predetermined resistance, capacitance and inductance. In addition, the wire 158 can avoid the different distributed reactance caused by inconsistent path lengths. Furthermore, because the wire 158 is shared by the first element 154 and the second element 156, instead of using two wires for separately feeding the input signal to the first element 154 and the second element 156 in the prior art layout, the unitization element 150 uses the common wire 158 for decreasing the wiring and shortening the path so as to reduce the induction between the lines and avoid the feedback oscillation. Besides, the wire 158 can be applied to passive element. This is substantially benefits the production and manufacturing of the resistance, capacitance and inductance.

FIG. 4 is a perspective diagram of an embodiment according to the present invention. The input signal is fed into the separate input end 166 from the common input end 162 in multi-level branches manner. The structure of the multi-level branches is similar to a tree structure. Thereafter, the input signal is separately fed to the unitization element 150 via the separate input ends 166. In this embodiment, the number of the unitization elements 150 along the vertical direction can be increased to any number, and the path lengths between the input signal and the unitization elements 150 are maintained to be consistent via the multi-level branches formed by the wires 164. Therefore, the distributed reactance is uniform. In addition, the unitization elements 150 are spaced at predetermined intervals so as to reduce the induction therebetween, and to avoid the feedback oscillation, as well as to facilitate the grounding of the unitization element 150.

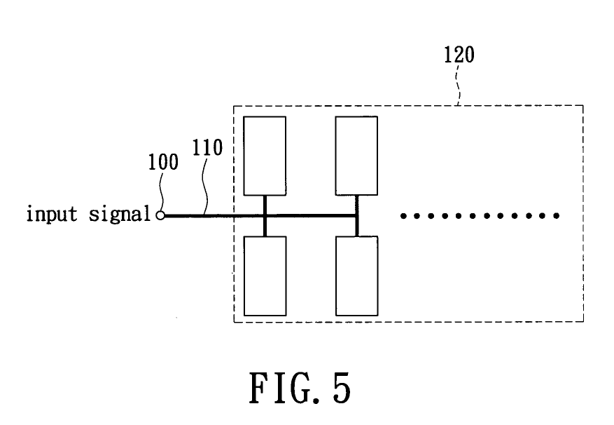

FIG. 5 is a perspective diagram of another feeding structure according to the present invention. The number of the transistors in the feeding unit 120 is increased along the horizontal direction, and the feeding unit 120 is connected to the input end 100 via a single wire 110. Therefore, the wire 110 is a feed-in wire for an input signal. Because the structure involves only one wire 110, the single feed-in wire structure minimizes the induction between the lines, and effectively reduces the feedback oscillation caused by the induction. Therefore, the heat caused by concentrated electric current can be avoided, the working efficiency can be promoted, and the lifespan of the transistor can be extended.

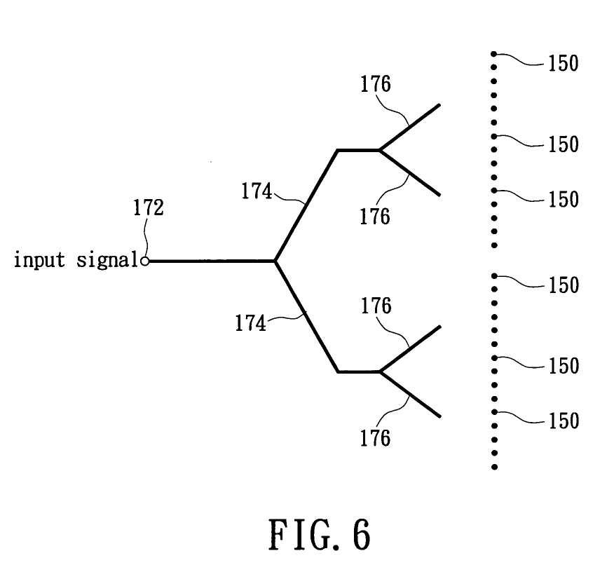

FIG. 6 is a perspective diagram of a structure with multi-level branches according to the present invention. The input signal is separately fed into each of the unitization elements 150 from the common input end 172 via the first level wires 174 and the second level wires 176. In FIG. 6, each of the points represents one unitization element 150, and the unitization elements 150 are spaced at predetermined intervals. The wires 174 and the second level wires 176 are arranged in multi-level branches manner so that the paths along which the input signal are fed in the unitization elements 150 are equidistant. Furthermore, the included angles between the wires 174 and between the second level wires 176 are manually adjustable. In this way, the scattering problem of the high frequency signals due to extremely sharp angles can be avoided. In addition, the possible wiring levels and the possible angles are not limited by this embodiment.

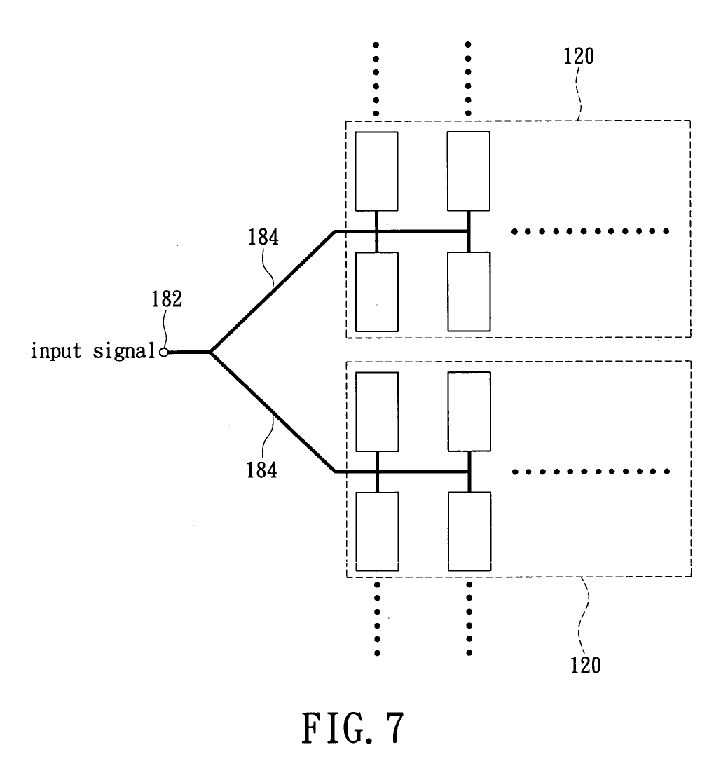

Reference is made to FIG. 7. The feeding unit 120 is formed by two-dimensional planar array layout. As shown in FIG. 7, the number of the feeding units 120 can be increased to any number along the horizontal direction and the vertical direction so as to form a square-shaped pattern with the same length and width. Therefore, the number of transistors installed in every unit area can be increased, and the layout is reduced. By applying the multi-level branches, the wires 184 are used for feeding the input signal in each of the feeding units 120 from the common input end 182. However, in practical semiconductor processes, the method according to the present invention is not limited to a two-dimensional planar array layout, and can be also applied to a three-dimensional space array layout as well.

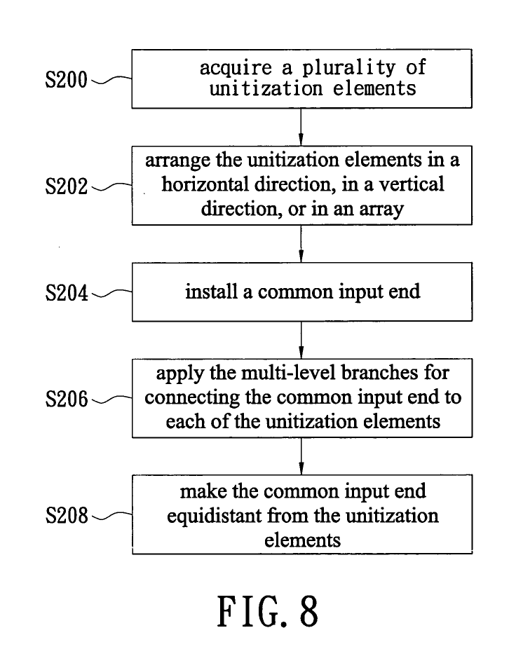

FIG. 8 is a flowchart of a method according to the present invention. First, a plurality of unitization elements 150 is provided (S200). Each of the unitization elements 150 comprises a first element 154 and a second element 156, and the first element 154 and the second element 156 can be the silicon-based structure with predetermined Si ratio. The unitization elements 150 can be arranged in a horizontal direction, in a vertical direction, or in an array to integrate more unitization elements 150 in a unit volume (S202). Then, a common input end is installed for receiving an input signal to be the common input end of the unitization elements 150 (S204). The common input end is connected to each of the unitization elements 150 in multi-level branches manner (S206). Therefore, the common input end is equidistant from the unitization elements 150, and the signal transmission paths have the same distance (S208). In this way, the object of reducing the array layout is achieved and the distributed effect and the effect caused by the induction between the lines can be alleviated.

In summary, based on multi-level branches architecture, the method and structure for the compact transistor array layout according to the present invention can make the transistors in the wafer arrange in an array, and the numbers of the transistors along the length and the width of the array are almost the same. In addition, each of the feeding units 120 is nearly equidistant from the common input end 182 and the path length between the feeding units 120 and the common input end 182 is shortened. In this way, the distributed reactance is effectively reduced so as to realize uniform conduction time for the transistors. The heat caused by the over-concentration of the electric current and the temperature can be avoided. The working efficiency can be promoted and the lifespan of the transistor can be extended. Therefore, the number of the transistors installed in one unit area can be increased to reduce layout area and decrease cost.

Those skilled in the art will readily observe that numerous modifications and alterations of the device may be made while retaining the teachings of the invention. Accordingly, the above disclosure should be construed as limited only by the metes and bounds of the appended claims.

1. A method for a compact transistor array layout, which is adapt for a bipolar transistor integration process and comprises:
providing a plurality of unitization elements and feeding an input signal from a common input end; and
connecting the common input end to each of the unitization elements in multi-level branches manner, wherein the common input end is equidistant from the unitization elements.

2. The method of claim 1, wherein the unitization elements are composed of a plurality of transistors.

3. The method of claim 1, wherein the multi-level branches are formed by connecting a plurality of wires, and the wires have an arrangement to provide predetermined resistance, capacitance and inductance.

4. The method of claim 1, wherein the unitization elements are arranged in horizontal order.

5. The method of claim 1, wherein the unitization elements are arranged in vertical order.

6. The method of claim 1, wherein the unitization elements are spaced at predetermined intervals.

7. The method of claim 3, wherein an included angle between two wires is manually adjustable.

8. A structure for a compact transistor array layout made by connecting a plurality of unitization elements, the structure comprising:
a plurality of unitization elements composed of a first element and a second element for receiving an input signal; and
a plurality of wires used for feeding the input signal in the unitization elements and arranged in multi-level branches manner so that the input signal is equidistant from the unitization elements.

9. The structure of claim 8, wherein the first element and the second element are composed of a plurality of transistors.

10. The structure of claim 8, wherein the wires provide predetermined resistance, capacitance and inductance.

11. The structure of claim 8, wherein the unitization elements are arranged in horizontal order.

12. The structure of claim 8, wherein the unitization elements are arranged in vertical order.

13. The structure of claim 8, wherein the unitization elements are spaced at predetermined intervals.

14. The structure of claim 8, wherein an included angle between two wires is manually adjustable

15. A structure for a compact transistor array layout, a multi-dimensional layout space thereof being formed by arranging a plurality of unitization elements in order, the structure comprising:
a plurality of unitization elements composed of a first element and a second element for receiving an input signal;
a multi-dimensional layout space formed by arranging the unitization elements in order; and
a plurality of wires used for feeding the input signal in the unitization elements and arranged in multi-level branches manner so that the input signal is equidistant from the unitization elements.

16. The structure of claim 15, wherein the first element and the second element are composed of a plurality of transistors.

17. The structure of claim 15, wherein the wires provide predetermined resistance, capacitance and inductance.

18. The structure of claim 15, wherein the unitization elements are arranged in an array with a horizontal arrangement to form the multi-dimensional layout space.

19. The structure of claim 15, wherein the unitization elements are spaced at predetermined intervals, and the unitization elements are arranged in an array with a vertical arrangement to form the multi-dimensional layout space.

20. The structure of claim 15, wherein an included angle between two wires is manually adjustable.
